(19) United States
(12) Patent Application Publication
(10) Pub. No.: US 2010/0320623 A1
(43) Pub. Date: Dec. 23, 2010

(54) SEMICONDUCTOR DEVICE AND METHOD FOR MANUFACTURING THE SAME

(75) Inventors: Soshi Kuroda, Kanagawa (JP); Masatoshi Yasunaga, Kanagawa (JP); Hironori Matsushima, Kanagawa (JP); Kenya Hironaga, Kanagawa (JP)

Correspondence Address: MCDERMOTT WILL & EMERY LLP, 600 13TH STREET, N.W., WASHINGTON, DC, 20005-3096, US

(73) Assignee: RENESAS ELECTRONICS CORPORATION

(21) Appl. No.: 12/792,166

(22) Filed: Jun. 2, 2010

(30) Foreign Application Priority Data
Jun. 19, 2009 (JP) 2009-146141

(51) Int. Cl. H01L 23/52; H01L 21/50

(52) U.S. Cl. 257/784; 438/113; 257/E23.141; 257/E21.499

(57) ABSTRACT

A multi-pin semiconductor device with improved reliability. In a multi-pin BGA, a plurality of wires for electrically coupling a semiconductor chip and a wiring substrate include a plurality of short and thin first wires located in an inner position and a plurality of second wires longer and thicker than the first wires. Since resin flows in from between thin first wires during resin molding, the resin pushes out air, thereby suppressing formation of voids. The reliability of the multi-pin BGA is thus improved.

### CROSS-REFERENCE TO RELATED APPLICATIONS

The disclosure of Japanese Patent Application No. 2009-146141 filed on Jun. 19, 2009 including the specification, drawings and abstract is incorporated herein by reference in its entirety.

### BACKGROUND OF THE INVENTION

The present invention relates to semiconductor devices and methods for manufacturing the same and more particularly to a technique which improves the reliability of a semiconductor device which is assembled by a process including wire bonding and resin molding.

For example, Japanese Unexamined Patent Publication No. 2003-60126 discloses a semiconductor device which is produced by a batch molding process in which resin molding is performed in a way to cover a plurality of device regions all together.

### SUMMARY OF THE INVENTION

In recent years, there has been a growing tendency toward highly functional semiconductor devices and thus toward multi-pin semiconductor devices. BGAs (Ball Grid Arrays) are known as multi-pin wire-bonded semiconductor devices. Some multi-pin BGAs have two rows of bonding leads around the chip mounting area of the substrate. In such BGAs, the wire loops are different in height so that one row of wires makes an upper tier and the other row of wires makes a lower tier.

More specifically, the loop height of wires to be coupled with boding leads in the outer row is higher than that of wires to be coupled with bonding leads in the inner row so that the wires to be coupled with the boding leads in the outer row and the wires to be coupled with the boding leads in the inner row do not interfere with each other. This results in a so-called multi-tier wire bonded BGA.

Multi-tier wire bonded BGAs have a problem that when the density of wires in the lower tier is high, sealing resin (hereinafter called “resin”) for resin molding may flow in the area under the wires in the lower tier less smoothly, resulting in formation of voids under the wires in the lower tier.

Also, in assembling a BGA, a multi-chip substrate, or a substrate which has a plurality of regions for devices, is usually used. Furthermore, in order to maximize the number of devices which can be obtained from a single substrate, the MAP (Mold Array Package) method is often adopted for the assembling process.

The MAP method is an assembling process in which resin molding is performed while the device regions of a multi-chip substrate are collectively covered by one cavity of the resin mold die of molding equipment, and after molding, the collective sealing body and substrate are cut into pieces at a time. In this method, in order to increase the number of devices obtained from a single substrate, in many cases device regions 10c are formed in a matrix pattern as illustrated in the comparative example of FIG. 13.

In the resin molding process based on the MAP method for a multi-chip substrate 10 in which multiple device regions are arranged in a matrix pattern as shown in the figure, there are areas where resin easily flows in and areas where resin hardly flows in, around a semiconductor chip 1 depending on the direction 11 in which injected resin flows (FIG. 13). In the multi-tier wire bonded BGA, if wires 7 are densely disposed in the lower tier, it is more difficult for the resin to flow in the area under the wires in the lower tier and as a consequence, the problem inherent in the MAP method arises that a void 21 is formed under the wires 7 in the lower tier (see FIGS. 14 and 15). In other words, when resin flows less smoothly in the area under the wires 7 in the lower tier, the air accumulated there cannot be pushed out by the resin, resulting in formation of a void 21.

To address this problem, the present inventors examined the assembling process for the BGA 20 as the comparative example and have come to conceive an approach to preventing formation of voids 21 in which thinner wires 7 are used in all multiple tiers to broaden gaps between neighboring wires to enable the resin to pass through them more easily.

However, since the wires 7 in the upper tier are coupled with the outer row of bonding leads on the substrate, their wire length is longer than the wire length of the wires 7 in the lower tier and thus the above approach would easily cause “wire sweep”. This might cause short-circuiting between neighboring wires 7.

The present invention has been made in view of the above problem and an object thereof is to provide a technique which improves the reliability of multi-pin semiconductor devices.

Another object of the present invention is to provide a technique which improves the reliability of the MAP method used for assembling semiconductor devices.

The above and further objects and novel features of the invention will more fully appear from the following detailed description in this specification and the accompanying drawings.

Typical aspects of the invention which are disclosed herein are briefly summarized below.

According to one aspect of the invention, there is provided a semiconductor device which includes: a wiring substrate having an upper surface, a plurality of boding leads formed over the upper surface, a lower surface opposite to the upper surface, and a plurality of lands formed over the lower surface; a semiconductor chip having a main surface and a plurality of electrode pads formed over the main surface and lying over the upper surface of the wiring substrate; a plurality of metal wires which electrically couple the bonding leads of the wiring substrate with the electrode pads of the semiconductor chip respectively; and a plurality of external terminals provided over the lands of the wiring substrate. The metal wires include a plurality of first wires and a plurality of second wires and the first wires are shorter and thinner than the second wires.

According to a second aspect of the invention, a method for manufacturing a semiconductor device using a multi-chip substrate having a plurality of device regions includes the steps of: (a) preparing the multi-chip substrate having an upper surface and a lower surface opposite to the upper surface with a plurality of bonding leads formed in each of the device regions of the upper surface and a plurality of lands formed over the lower surface; (b) mounting a plurality of semiconductor chips, each of which has a plurality of electrode pads formed over its main surface, over the device regions of the upper surface of the multi-chip substrate; (c) supplying sealing resin to the upper surface of the multi-chip substrate to form a collective sealing body with the bonding leads of the multi-chip substrate electrically coupled with the electrode pads of each of the semiconductor chips by metal wires, covering the semiconductor chips and the metal wires with the collective sealing body; and (d) cutting the collective sealing body and the multi-chip substrate into pieces. The metal wires include a plurality of first wires and a plurality of second wires, the first wires are shorter and thinner than the second wires and in the step (C), the sealing resin is made to flow under the first wires to form the collective sealing body.

The advantageous effects brought about by the preferred embodiment of the present invention as disclosed herein are briefly described below.

In the multi-pin semiconductor device, since the metal wires include short and thin first wires and long and thick second wires, so resin molding, resin flows in through gaps between thin first wires and pushes out air, thereby suppressing formation of voids. As a consequence, the reliability of the multi-pin semiconductor device is improved.

In assembling a semiconductor device by the MAP method, formation of voids during resin molding is suppressed, so the reliability of the MAP method used for assembling a semiconductor device is improved.

### BRIEF DESCRIPTION OF THE DRAWINGS

FIG. 1 is a plan view of an example of the structure of a semiconductor device according to a preferred embodiment of the invention, as seen through a sealing body;

FIG. 2 is a sectional view showing an example of the structure of the semiconductor device shown in FIG. 1;

FIG. 3 is a fragmentary enlarged sectional view showing part A shown in FIG. 2 in enlarged form;

FIG. 4 is a flowchart showing an example of the sequence of assembling the semiconductor device shown in FIG. 1;

FIG. 5 is a plan view showing an example of the structure of a multi-chip substrate as used in assembling the semiconductor device shown in FIG. 1;

FIG. 6 is a plan view showing an example of the structure after die bonding in the process of assembling the semiconductor device shown in FIG. 1;

FIG. 7 is a plan view showing an example of the structure after wire bonding in the process of assembling the semiconductor device shown in FIG. 1;

FIG. 8 is a plan view showing an example of the structure just after resin injection in the resin molding step of the process of assembling the semiconductor device shown in FIG. 1;

FIG. 9 is a plan view showing an example of the structure before completion of resin injection in the resin molding step of the process of assembling the semiconductor device shown in FIG. 1;

FIG. 10 is a fragmentary enlarged sectional view taken along the line A-A in FIG. 9;

FIG. 11 is a fragmentary enlarged sectional view taken along the line B-B in FIG. 9;

FIG. 12 is a plan view showing an example of the structure after resin molding in the process of assembling the semiconductor device shown in FIG. 1;

FIG. 13 is a plan view showing an example of the structure just before completion of resin injection in the resin molding step of the process of assembling a semiconductor device as a comparative example;

FIG. 14 is a plan view showing formation of voids in the process of assembling the semiconductor device as the comparative example; and

FIG. 15 is a fragmentary enlarged sectional view showing formation of a void in the semiconductor device as the comparative example.

### DETAILED DESCRIPTION OF THE PREFERRED EMBODIMENTS

Basically, in description of the preferred embodiments given below, repeated descriptions of like elements are omitted except when necessary.

The preferred embodiments below will be described separately as necessary, but such descriptions are not irrelevant to each other unless otherwise specified. They are, in whole or in part, variations of each other and sometimes one description is a detailed or supplementary form of another.

Also, in the preferred embodiments described below, even when the numerical datum for an element (the number of pieces, numerical value, quantity, range, etc.) is indicated by a specific numerical value, it is not limited to the indicated specific numerical value unless otherwise specified or theoretically limited to the specific numerical value; it may be larger or smaller than the specific numerical value.

In the preferred embodiments described below, it is needles to say that their constituent elements (including constituent steps) are not necessarily essential unless otherwise specified or considered theoretically essential.

In the preferred embodiments described below, regarding constituent elements or the like, when the inventors say that (something) “is comprised of A”, “comprises A”, “has A”, or “includes A”, it does not exclude the possibility that (something) may have another element unless it is explicitly indicated that it does not have any other element than A. Likewise, in the preferred embodiments described below, when a specific form or positional relation is indicated for an element, it should be interpreted to include a form or positional relation which is virtually equivalent or similar to the specific one unless otherwise specified or unless theoretically it must be the specific one. The same can be said of numerical values or ranges as mentioned above.

Next, the preferred embodiments of the present invention will be described in detail referring to the accompanying drawings. In all the drawings that illustrate the preferred embodiments, elements with like functions are basically designated by like reference numerals and repeated descriptions thereof are omitted.

### First Embodiment

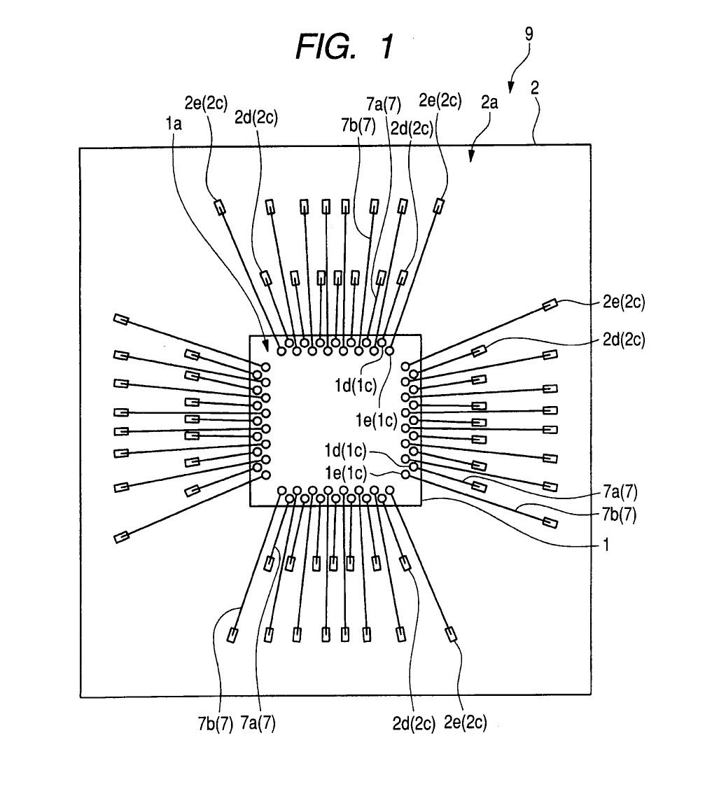

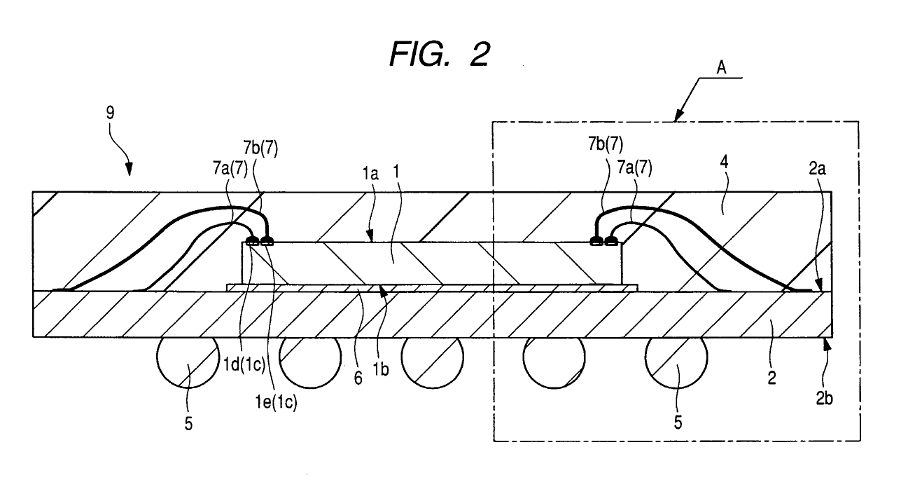

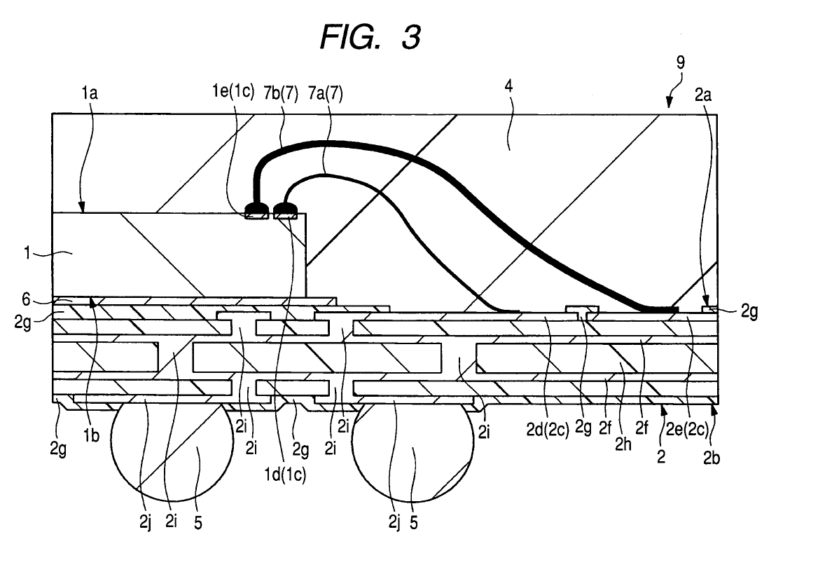

FIG. 1 is a plan view showing an example of the structure of a semiconductor device according to a first embodiment of the present invention, as seen through a sealing body, FIG. 2 is a sectional view showing an example of the structure of the semiconductor device shown in FIG. 1, and FIG. 3 is a fragmentary enlarged sectional view showing part A shown in FIG. 2 in enlarged form.

In the semiconductor device according to this embodiment as shown in FIGS. 1 to 3, a semiconductor chip 1 mounted over the upper surface 2a of a wiring substrate 2 is resin-sealed with a sealing body 4 and the semiconductor chip 1 is electrically coupled with bonding leads 2c of the wiring substrate 2 by wires 7. In the description of this embodiment, a BGA 9, in which a plurality of solder balls 5 as external terminals are arranged in a grid pattern on the lower surface 2b of the wiring substrate 2, is adopted as an example of the above semiconductor device.

Specifically the BGA 9 includes: a wiring substrate (also called a BGA substrate) having an upper surface 2a, a plurality of boding leads 2c formed over the upper surface 2a, a lower surface 2a opposite to the upper surface 2a, and a plurality of lands 2j formed over the lower surface 2b; a semiconductor chip 1 having a main surface 1a and a plurality of electrode pads 1c formed over the main surface 1a and lying over the upper surface 2a of the wiring substrate 2; a plurality of wires (metal wires) 7 which electrically couple the bonding leads 2c of the wiring substrate 2 with the electrode pads 1c of the semiconductor chip 1 respectively; and a plurality of solder balls 5 as external terminals provided over the lands 2j of the wiring substrate 2.

In other words, the BGA 9 is a semiconductor package in which the semiconductor chip 1 is mounted over the wiring substrate 2 and coupled with the wiring substrate 2 by wires and the semiconductor chip 1 and plural wires 7 are sealed with a resin sealing body 4.

As illustrated in FIG. 2, the semiconductor chip 1 is bonded to the upper surface 2a of the wiring substrate 2 with die bond 6 such as resin paste. In other words, the back surface 1b of the semiconductor chip 1 and the upper surface 2a of the wiring substrate 2 are joined through the die bond 6.

For example, the semiconductor chip 1 is made of silicon and the wires 7 are copper wires or more preferably gold wires. The sealing resin used for the sealing body 4 is, for example, thermosetting epoxy resin. The external terminals are solder balls 5 made of a solder material.

The wiring substrate 2 is a multilayer substrate having a plurality of interconnect layers which each make up an interconnect region 2f in a layer, as illustrated in FIG. 3. The interconnect layers are formed for a core material 2h such as glass epoxy resin and the interlayer interconnect regions 2f are electrically coupled by via interconnections 2i. The regions other than the first bonding leads 2d and second bonding leads 2e which are exposed on the upper surface 2a and the lands 2j which are exposed on the lower surface 2b are covered by a solder resist film 2g, an insulating film. The interconnect regions 2f, bonding leads 2c, via interconnections 2i and lands 2j in each layer are made of, for example, copper alloy.

In this way, the electrode pads 1c and the solder balls 5 as the external terminals of the BGA 9 are electrically coupled by the wires 7, bonding leads 2c, interconnect regions 2f, via interconnections 2i and lands 2j.

Though the BGA 9 has several hundred pins, for example, 680 pins, the number of pins shown in FIG. 1 is smaller than the actual number of pins for the sake of simplified illustration.

Since the BGA 9 has many pins, it is designed to prevent contact between neighboring wires.

First, as illustrated in FIG. 1, the plural electrode pads is are arranged in a staggered pattern on the peripheral areas of the main surface 1a of the semiconductor chip 1. In addition, the bonding leads 2c are also arranged in a staggered pattern on the four sides of the semiconductor chip 1 over the wiring substrate 2. This makes it possible that the electrode pads 1c staggered in two rows are electrically coupled with the bonding leads 2c staggered in two rows.

The wires 7 include a plurality of first wires 7a and a plurality of second wires 7b. Regarding the two rows of electrode pads 1c and the two rows of bonding leads 2c, the first electrode pads 1d in the outer row and the first bonding leads 2d in the inner row are electrically coupled by the first wires 7a and the second electrode pads 1e in the inner row and the second bonding leads 2e in the outer row are electrically coupled by the second wires 7b.

In other words, the first wires 7a are electrically coupled with the first bonding leads 2d in the inner row and the second wires 7b are electrically coupled with the bonding leads 2e in the outer row.

As illustrated in FIGS. 2 and 3, the loop height of each of the first wires 7a is lower than the loop height of each of the second wires 7b. More specifically, regarding the first wires 7a and second wires 7b, the first wires 7a are located on the inside of the second wires 7b and the loop height of the second wires 7b is higher than the loop height of the first wires 7a (i.e. there is a height difference between the first wires 7a and the second wires 7b) so that the first wires 7a and the second wires 7b do not interfere (contact) with each other. As a consequence, wiring can be made without interference between wires for neighboring electrode pads 1c. From another point of view, the second wires 7b in an upper position or tier are longer than the first wires 7a in a lower position or tier.

In the BGA 9 according to this embodiment, the diameter of each of the first wires 7a is smaller than the diameter of each of the second wires 7b as illustrated in FIG. 3. More specifically, each of the first wires 7a is smaller in diameter and shorter in length than each of the second wires 7b. In short, as for the wires 7, the wires 7 in the lower tier (first wires 7a) are thinner and shorter than the wires 7 in the upper tier (second wires 7b).

For example, the thickness (diameter) of the first wires 7a is between φ16 μM and φ20 μm and the thickness (diameter) of the second wires 7b is between φ23 μm and φ28 μm. The difference in thickness (diameter) is approximately between 3 μM and 8 μm. However, the thickness of the first wires 7a and that of the second wires 7b and the thickness difference between them are not limited to the above numerical values.

Thus, according to this embodiment, in the BGA 9, as for the first wires 7a and second wires 7b arranged on the four sides of the main surface 1a of the semiconductor chip 1, the first wires 7a in the inner (lower) position are shorter and thinner than the second wires 7b in the outer (upper) position.

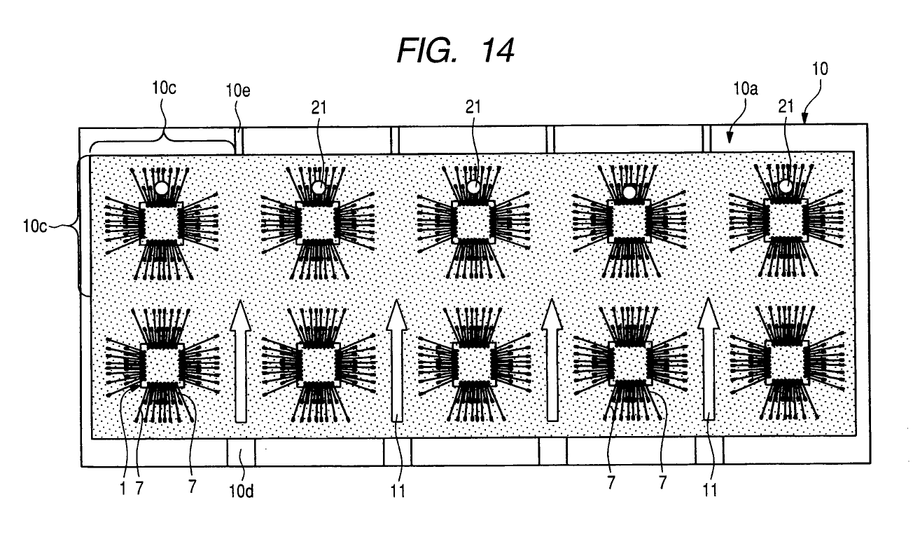

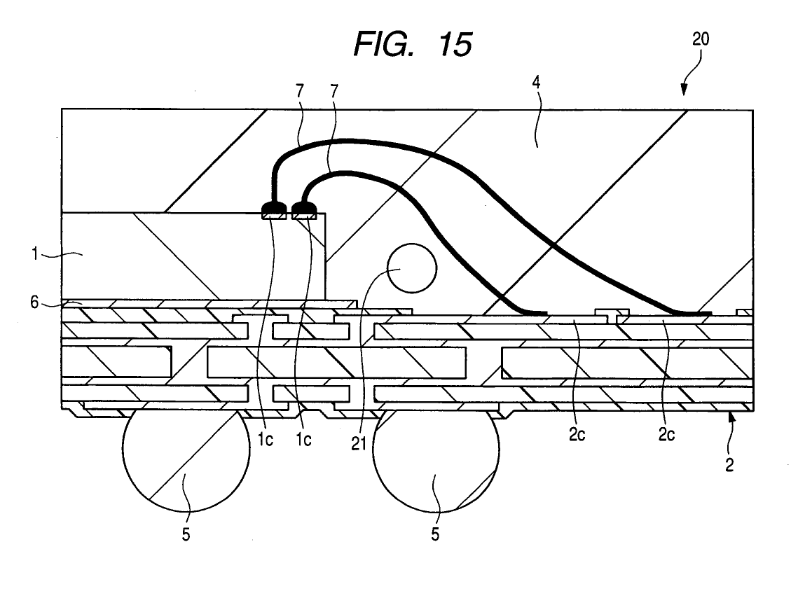

According to this embodiment, in the multi-pin BGA 9, since the wires 7 for electrically coupling the semiconductor chip 1 with the wiring substrate 2 include the short and thin first wires 7a and the second wires 7b longer and thicker than the first wires 7a, sealing resin flows through gaps between first wires 7a into the area on the inside of the wires during resin molding and the air generated on the inside of the first wires 7a is pushed out by the resin, thereby suppressing formation of voids 21 as shown in FIGS. 14 and 15.

As a consequence, the reliability of the multi-pin BGA 9 is improved.

When the BGA 9 is of the multi-pin type and has a multi-tier (two-tier) wire bonded structure which includes first wires 7a in the lower tier and second wires 7b in the upper tier, during resin molding voids 21 formed on the inside of the first wires 7a in the lower tier are pushed out by the resin flowing through the gaps between thin first wires 7a into the area inside the wires, thereby suppressing formation of voids 21 in the multi-tier wire bonded BGA 9.

As a consequence, the reliability of the multi-pin multi-tier wire bonded BGA 9 is improved.

In the multi-tier wire bonded BGA 9, since the thickness of the wires 7 in the lower tier (first wires 7a) is smaller than that of the wires 7 in the upper tier, if the wires 7 are gold wires, the required amount of gold is smaller than when all the wires 7 have the same thickness, resulting in cost reduction of the BGA 9.

Next, the method for manufacturing the BGA (semiconductor device) 9 according to this embodiment will be described.

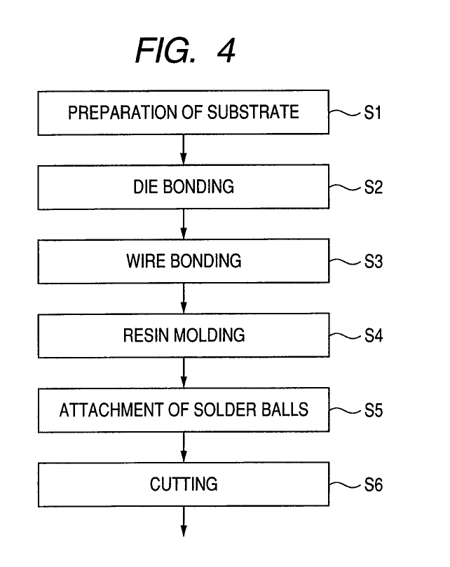

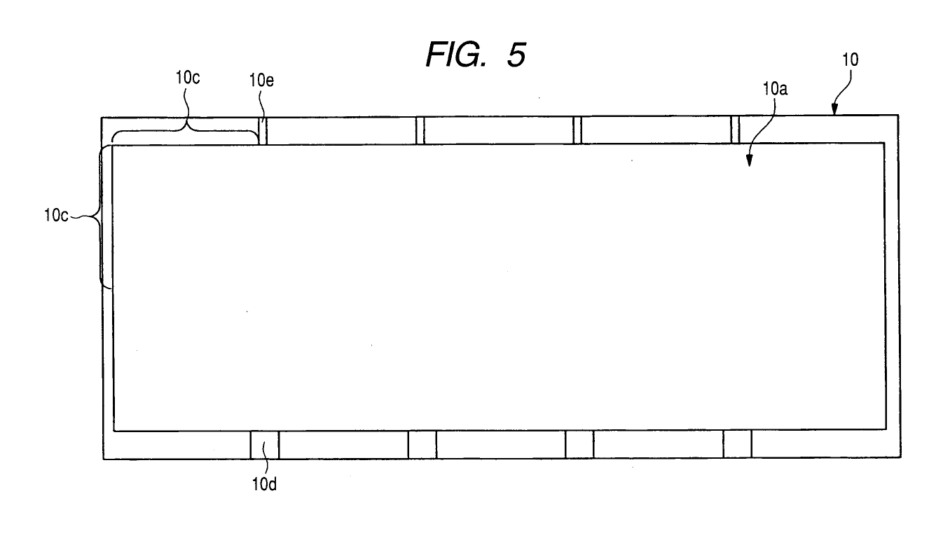

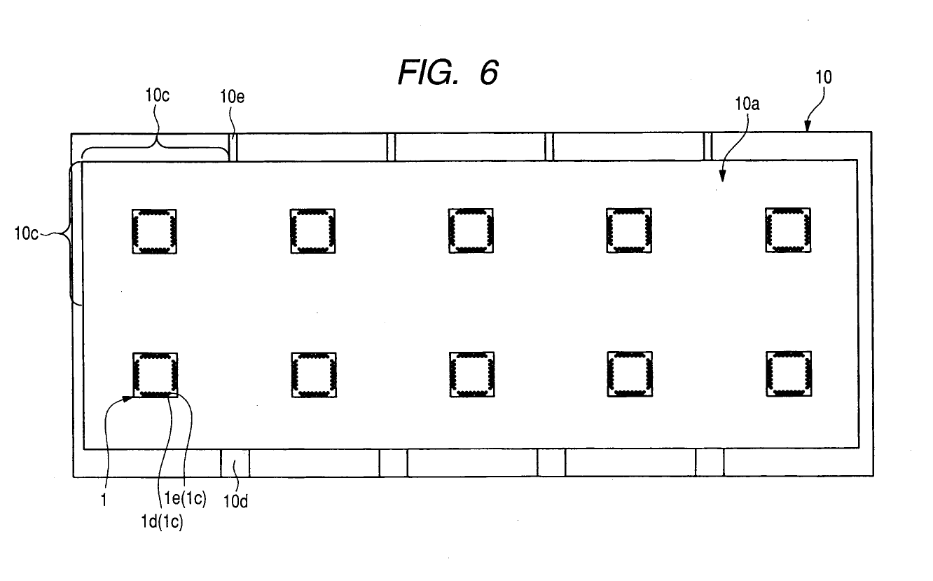

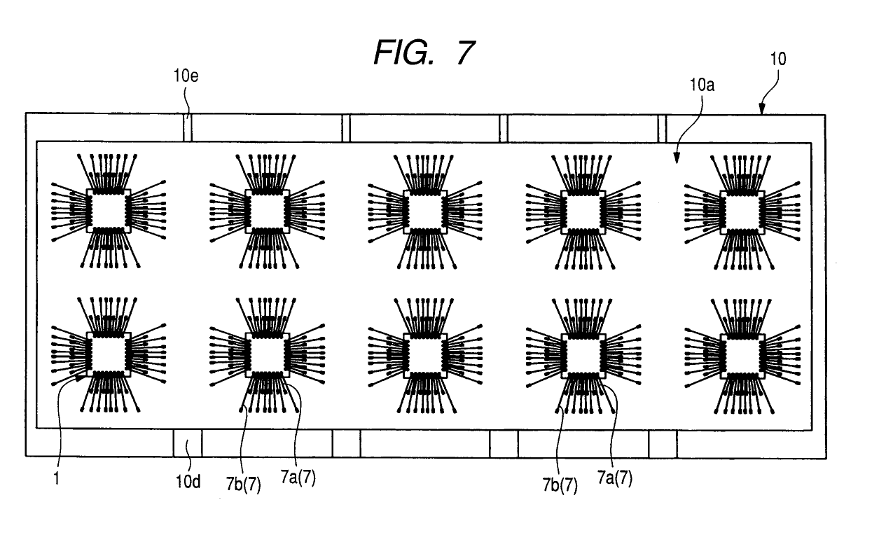

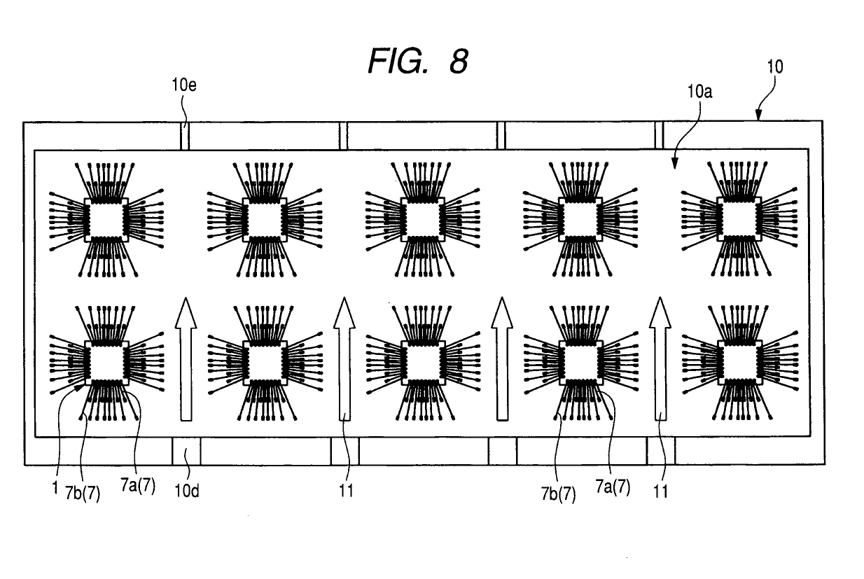

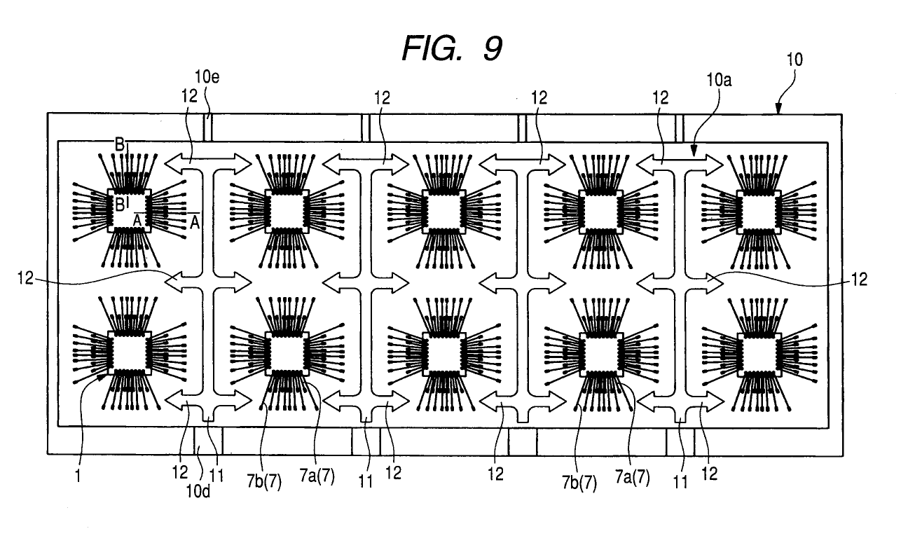

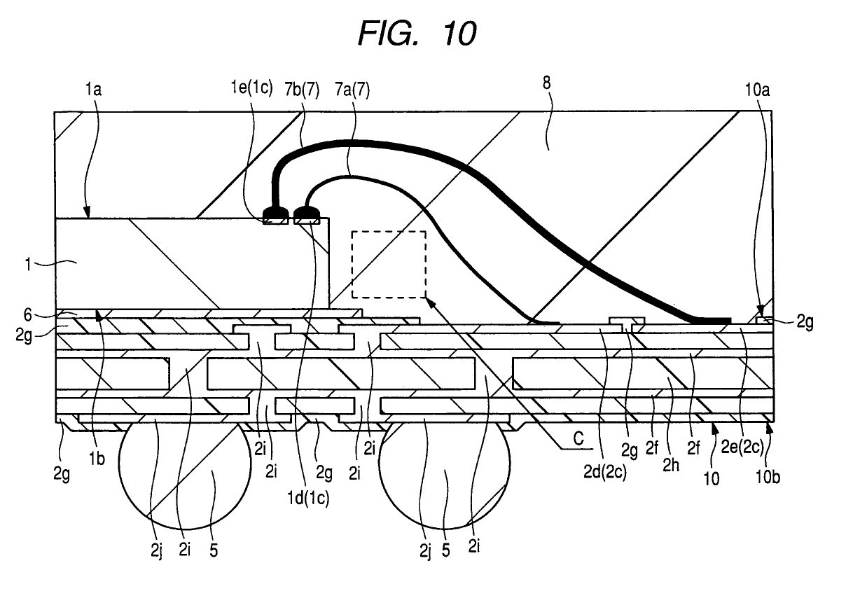

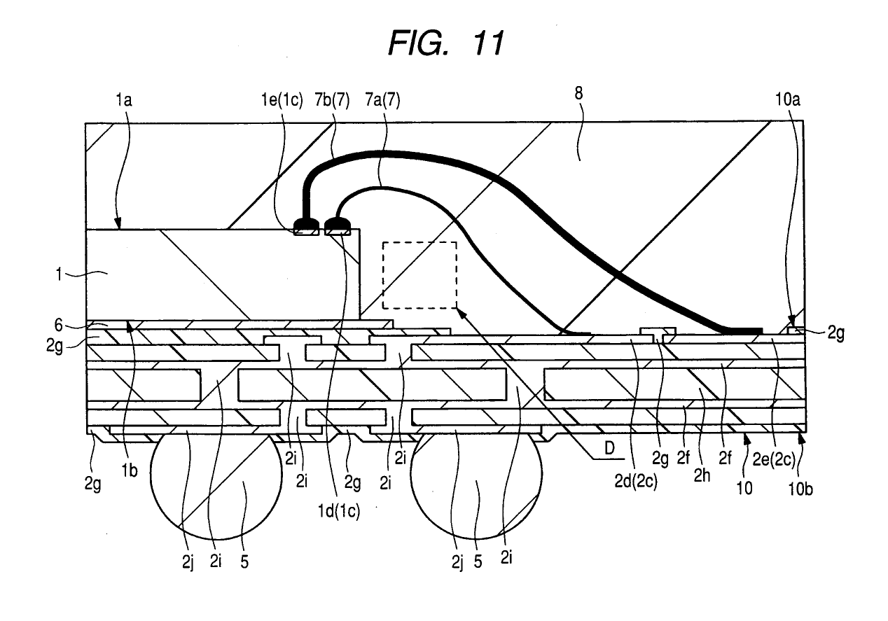

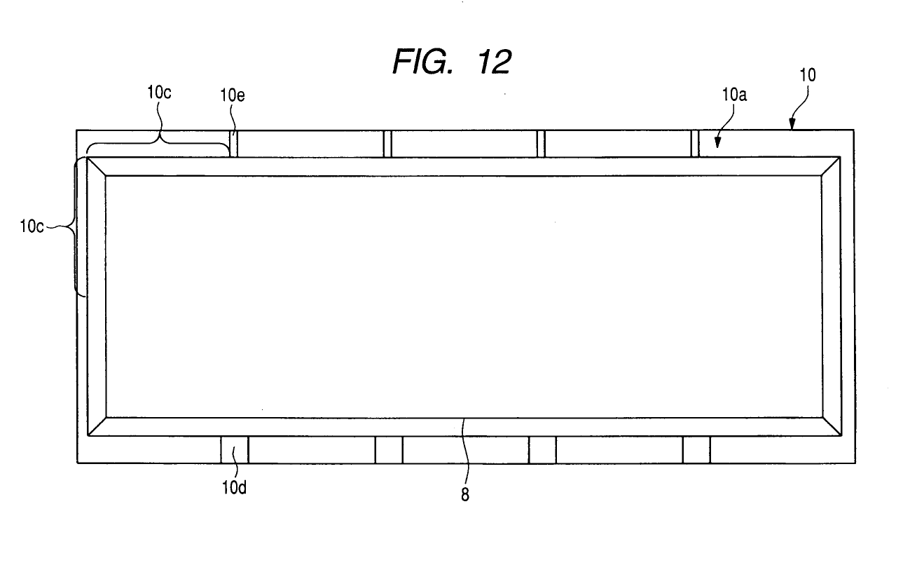

FIG. 4 is a flowchart showing an example of the sequence of assembling the semiconductor device shown in FIG. 1; FIG. 5 is a plan view showing an example of the structure of a multi-chip substrate used in assembling the semiconductor device shown in FIG. 1; FIG. 6 is a plan view showing an example of the structure after die bonding in the process of assembling the semiconductor device shown in FIG. 1; and FIG. 7 is a plan view showing an example of the structure after wire bonding in the process of assembling the semiconductor device shown in FIG. 1. FIG. 8 is a plan view showing an example of the structure just after resin injection in the resin molding step of the process of assembling the semiconductor device shown in FIG. 1; and FIG. 9 is a plan view showing an example of the structure before completion of resin injection in the resin molding step of the process of assembling the semiconductor device shown in FIG. 1. FIG. 10 is a fragmentary enlarged sectional view taken along the line A-A in FIG. 9; FIG. 11 is a fragmentary enlarged sectional view taken along the line B-B in FIG. 9; and FIG. 12 is a plan view showing an example of the structure after resin molding in the process of assembling the semiconductor device shown in FIG. 1.

First, a substrate is prepared (Step S1 in FIG. 4). Here the so-called MAP method is explained below in which a multi-chip substrate 10 which has a plurality of device regions 10c as shown in FIG. 5 is used for the assembling process.

The multi-chip substrate 10 has an upper surface 10a and a lower surface 10b opposite to the upper surface 10a and as illustrated in FIG. 10, a plurality of bonding leads 2c are formed in each of the device regions 10c of the upper surface 10a and a plurality of lands 2j are formed on the lower surface 10b. The device regions 10c are arranged in a matrix pattern.

In each device region 10c of the multi-chip substrate 10, as illustrated in FIG. 10, a plurality of boding leads 2c are arranged in two rows (inner and outer rows) in a way to surround the semiconductor chip 1. Plural metal areas 10d for gates are formed on one longitudinal side of the rectangular substrate 10 and a plurality of slits 10e for air vents are formed on the other longitudinal side so that the metal areas 10d for gates and the slits 10e for air vents face each other in a way to demarcate a border between neighboring device regions 10c. For example, the slits 10e for air vents are made of solder resist.

After that, die bonding is carried out (Step S2 in FIG. 4). In this step, a plurality of semiconductor chips 1, each having a plurality of electrode pads 1c on the main surface 1a, are mounted in the device regions of the upper surface 10a of the multi-chip substrate 10 as illustrated in FIG. 6. At this time, each semiconductor chip 1 is bonded to the multi-chip substrate 10 through die bond 10 such as resin paste.

Plural electrode pads 1c are arranged in a staggered pattern on the peripheral areas of the main surface 1a of each semiconductor chip 1. More specifically, first electrode pads 1d in an outer row and second electrode pads 1e in an inner row are arranged in a staggered pattern along each of the four sides of the main surface 1a.

After that, wire bonding is carried out (Step S3 in FIG. 4). In this case, gold wires are used as the metal wires 7, though instead they may be copper or other metal wires. Wires of two different thicknesses are used for the wires 7. For example, gold wires whose thickness (diameter) is between φ16 μm and φ20 μm are used as the first wires 7a and gold wires whose thickness (diameter) is between φ23 μm and φ28 μm are used as the second wires 7b. The difference in thickness (diameter) between the first wires 7a and second wires 7b is, for example, approximately between 3 μm and 8 μm.

First, among the electrode pads is arranged in a staggered pattern on the main surface 1a of each semiconductor chip 1, the first electrode pads 1d in the outer row and the first bonding leads 2d in the inner row in the corresponding device region 10c of the multi-chip substrate 10 are electrically coupled by the first wires 7a as illustrated in FIG. 7.

In other words, the inner or first wires 7a are all coupled on all the four sides of the semiconductor chip 1.

Then, among the electrode pads 1c arranged in a staggered pattern on the semiconductor chip 1, the second electrode pads 1e in the inner row and the second bonding leads 2e in the outer row in the corresponding device region 10c of the multi-chip substrate 10 are electrically coupled by the second wires 7a.

In other words, the outer or second wires 7b are all coupled on all the four sides of the semiconductor chip 1.

This wire bonding step is carried out in a manner that the loop height of each of the second wires 7b is higher than the loop height of each of the first wires 7a as illustrated in FIG. 10. To put it another way, wire boding is carried out in a manner that the loop height of each of the first wires 7a is lower than the loop height of each of the second wires 7b.

Since the first wires 7a are located on the inside of the second wires 7b and the first wires 7a and second wires 7b are bonded differently in height in this way, inevitably the second wires 7b should be longer than the first wires 7a.

Therefore, in wire bonding, the thinner and shorter first wires in the inner position and lower tier are first bonded all around the chip with a smaller loop height and then the thicker and longer second wires 7b in the outer position and upper tier are bonded all around the chip with a loop height larger than the loop height of the first wires 7a, completing a multi-tier wire bonded structure.

Since the first wires 7a in the inner position are thin, these wires, or wires in the lower tier, form a wire bonded structure with gaps between neighboring wires.

After that, resin molding is carried out (Step S4 in FIG. 4). At this step, while the bonding leads 2c of the multi-chip substrate 10 are coupled with the electrode pads is of each of the semiconductor chips 1 of the substrate 10 by wires 7, sealing resin is supplied to the upper surface 10a of the multi-chip substrate 10 to form a collective sealing body 8 as illustrated in FIG. 12, covering the plural semiconductor chips 1 and wires 7 with the collective sealing body 8. In other words, the plural device regions 10c of the multi-chip substrate 10 (which hold the plural semiconductor chips 1 and the plural wires 7) are collectively covered by the collective sealing body 8.

In the resin molding step, the multi-chip substrate 10 for which wire boding has been finished is placed in a resin molding die (not shown) and while one cavity of the resin molding die is covering the device regions 10c of the multi-chip substrate 10, sealing resin is supplied into the resin molding die to form the collective sealing body 8.

At this time, resin is injected through the gate metal areas 10d of the multi-chip substrate 10 so that it flows along the direction 11 as illustrated in FIG. 8 and the areas around the semiconductor chips 1 are filled with resin due to side flows 12 of resin as illustrated in FIG. 9. In this embodiment, since the first wires 7a in the lower tier are thin and there are gaps between neighboring first fires 7a, when covering the semiconductor chips 1, resin can flow through the gaps to form the collective sealing body 8, ensuring that resin is filled under (inside) the first wires 7a.

In other words, in this embodiment, voids 21 formed on the inside of the wires 7 in the lower tier as illustrated in the comparative example of FIGS. 14 and 15 are brought outside of the first wires 7a by resin and consequently there are no voids 21 on the inside of the first wires 7a in the lower tier as indicated by C in FIG. 10 and D in FIG. 11.

More specifically, the resin flowing through gaps between thin first wires 7a into the area inside them pushes out voids 21 and consequently suppresses formation of voids 21 in the multi-tier wire bonded BGA 9.

Since the first wires 7a are located on the inside of (under) the second wires 7b and shorter than the second wires 7b, the possibility of wire sweep is very low even though the wire diameter is small (wires 7 are thin).

The reliability of the BGA 9, which is of the multi-pin and multi-tier wire bonded type, is thus improved. Even in the process of assembling the BGA 9 by the MAP method according to this embodiment, formation of voids 21 during resin molding can be suppressed, thereby improving the reliability of the MAP method used for assembling the BGA 9.

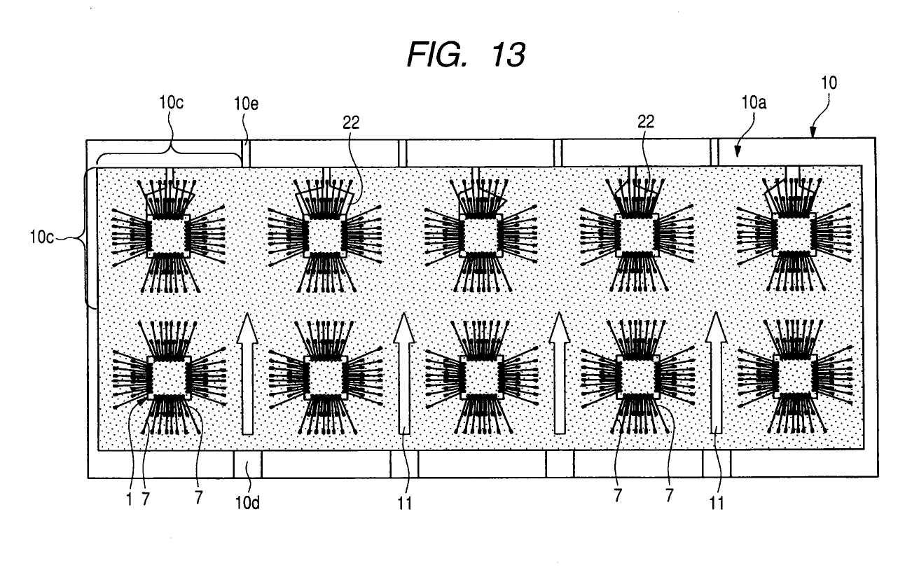

Particularly, the MAP method has a problem with the resin molding step that as resin is injected from the gate metal area 10d along the resin flow direction as illustrated in the comparative example of FIG. 13, air bubbles 22 easily accumulate beside the semiconductor chip 1 (in the area under the lower wires 7) on the most downstream (remotest) side in the resin flow direction 11, leading to formation of voids 21. Therefore, when the first wires 7a in the lower tier are small in diameter and gaps between wires are broadened as in this embodiment, resin can flow into the area under the first wires 7a and force out air bubbles 22 so that formation of voids 21 is effectively suppressed.

In assembling the BGA 9 according to this embodiment, when gold wires are used as the wires 7, the smaller the thickness of the first wires 7a is, the smaller amount of gold is used, leading to reduction in the manufacturing cost involved in the assembly of the multi-tier wire bonded BGA 9.

After resin molding is finished, solder balls are mounted (Step S5 in FIG. 4). As illustrated in FIG. 3, solder balls 5 are attached to the lands 2j on the lower surface 2b of the substrate 2.

After that, cutting is done (Step S6). More specifically, the multi-chip substrate 10 is cut, together with the collective sealing body 8 formed by resin molding as shown in FIG. 12, into individual devices and the assembly of the multi-tier wire bonded BGA 9 as shown in FIG. 1 is thus finished.

Among the wires 7 to be bonded on the four sides of each semiconductor chip 1, the first wires 7a in the lower tier need not be thin on all the four sides but only wires 7a located in a specific area on the four sides may be thin.

For example, it is possible that the first wires 7a located only on the remoter side (downstream side) of each semiconductor chip 1 in the resin flow direction 11 are thin or that the first wires 7a located only on the most upstream side of each semiconductor chip 1 in the resin flow direction 11 are thinner than the second wires 7b. In the latter case, the wiring direction is the same as the resin flow direction 11, so even when the first wires 7a located on the upstream side are thin, wire sweep hardly occurs and voids are effectively suppressed.

The invention made by the present inventors has been so far concretely explained in reference to the preferred embodiment thereof. However, the invention is not limited thereto and it is obvious that these details may be modified in various ways without departing from the spirit and scope thereof.

Although the above embodiment concerns the BGA 9 as an example of a semiconductor device, the invention is applicable to another type of semiconductor device such as LGA (Land Grid Array) as far as the semiconductor device is assembled using a wiring substrate with semiconductor chips 1 mounted thereon by a process including wire bonding and resin molding steps.

The present invention is suitable for wire-bonded electronic devices.

What is claimed is:

1. A semiconductor device comprising:
a wiring substrate having: an upper surface; a plurality of boding leads formed over the upper surface; a lower surface opposite to the upper surface; and a plurality of lands formed over the lower surface;
a semiconductor chip having a main surface and a plurality of electrode pads formed over the main surface, and lying over the upper surface of the wiring substrate;
a plurality of metal wires which electrically couple the bonding leads of the wiring substrate with the electrode pads of the semiconductor chip respectively; and
a plurality of external terminals provided over the lands of the wiring substrate,
wherein the metal wires include a plurality of first wires and a plurality of second wires, and
wherein the first wires are shorter and thinner than the second wires.

2. The semiconductor device according to claim 1, wherein the electrode pads of the main surface of the semiconductor chip are arranged in a staggered pattern on a peripheral area of the main surface.

3. The semiconductor device according to claim 2, wherein a loop height of each of the first wires is lower than a loop height of each of the second wires.

4. The semiconductor device according to claim 3, wherein the metal wires are gold wires.

5. The semiconductor device according to claim 4,
wherein the bonding leads are arranged in a plurality of rows, and
wherein the first wires are electrically coupled with the bonding leads in an inner one of the rows and the second wires are electrically coupled with the bonding leads in an outer row.

6. A method for manufacturing a semiconductor device using a multi-chip substrate having a plurality of device regions, the method comprising the steps of:
(a) preparing the multi-chip substrate having an upper surface and a lower surface opposite to the upper surface with a plurality of bonding leads formed in each of the device regions of the upper surface and a plurality of lands formed over the lower surface;
(b) mounting a plurality of semiconductor chips, each of which has a plurality of electrode pads formed over its main surface, over the device regions of the upper surface of the multi-chip substrate;
(c) supplying sealing resin to the upper surface of the multi-chip substrate to form a collective sealing body with the bonding leads of the multi-chip substrate electrically coupled with the electrode pads of each of the semiconductor chips by metal wires, covering the semiconductor chips and the metal wires with the collective sealing body; and
(d) cutting the collective sealing body and the multi-chip substrate into pieces,
wherein the metal wires include a plurality of first wires and a plurality of second wires,
wherein the first wires are shorter and thinner than the second wires, and
wherein in the step (C), the sealing resin is made to flow under the first wires to form the collective sealing body.

7. The method for manufacturing a semiconductor device according to claim 6, wherein the semiconductor chip has the electrode pads arranged in a staggered pattern on a peripheral area of the main surface.

8. The method for manufacturing a semiconductor device according to claim 7, wherein a loop height of each of the first wires is lower than a loop height of each of the second wires.

9. The method for manufacturing a semiconductor device according to claim 8, wherein the metal wires are gold wires.

10. The method for manufacturing a semiconductor device according to claim 9,
wherein the bonding leads are arranged in a plurality of rows, and
wherein the first wires are electrically coupled with the bonding leads in an inner one of the rows and the second wires are electrically coupled with the bonding leads in an outer row.

11. The method for manufacturing a semiconductor device according to claim 6, wherein among the first wires arranged on four sides of the semiconductor chip, only the first wires located upstream in a flow of the sealing resin for supplying the sealing resin to the upper surface of the multi-chip substrate in the step (C) are thinner than the second wires.

12. The method for manufacturing a semiconductor device according to claim 6, further comprising, after the step (B) and before the step (c), a step of:
electrically coupling the electrode pads of the semiconductor chip with the bonding leads in an inner row in the device region of the multi-chip substrate by the fist wires, and then electrically coupling the electrode pads of the semiconductor chip with the bonding leads in an outer row in the device region of the multi-chip substrate by the second wires.
